(19) United States
(12) Patent Application Publication
(10) Pub. No.: US 2026/0150266 A1
(43) Pub. Date: May 28, 2026

(54) MEMORY DEVICE AND MANUFACTURING METHOD THEREOF

(71) Applicant: SK hynix Inc., Gyeonggi-do (KR)

(72) Inventors: Kyung Kyu MIN, Gyeonggi-do (KR); Seong Wan RYU, Gyeonggi-do (KR)

(21) Appl. No.: 19/177,649

(22) Filed: Apr. 14, 2025

(30) Foreign Application Priority Data
Nov. 22, 2024 (KR) 10-2024-0168413

(51) Int. Cl. H10B 12/00

(52) U.S. Cl. CPC H10B 12/34; H10B 12/053; H10B 12/315

(57) ABSTRACT

According to embodiments of the present disclosure, a memory device may include a substrate including a cell area where memory cells are disposed and an extended area outside the cell area; a first gate electrode layer buried in the substrate and extending from the cell area to the extended area in a set direction, an upper surface of the first gate electrode layer in the cell area being located at substantially the same level as the upper surface of the first gate electrode layer in the extended area; a second gate electrode layer disposed on the first gate electrode layer, and extending from the cell area to the extended area in the set direction; and a word line contact located in the extended area, and extending into the second gate electrode layer in a vertical direction, vertical to the set direction.

### CROSS-REFERENCE TO RELATED APPLICATION

The present application claims priority under 35 U.S.C. § 119(a) to Korean Patent Application No. 10-2024-0168413 filed on Nov. 22, 2024, which is incorporated herein by reference in its entirety.

### BACKGROUND

### 1. Technical Field

Embodiments of the present disclosure relate to a memory device and a method for manufacturing the same.

### 2. Related Art

Memory devices are attracting attention as an important element in the electronics industry due to their characteristics such as miniaturization, multifunctionality and/or low manufacturing cost. As the electronics industry has developed rapidly, memory devices are becoming increasingly highly integrated. In order for high integration of memory devices, the line width of wirings included in the memory devices is gradually decreasing and the size of memory cells is becoming smaller. Due to this fact, the difficulty of forming memory cells is increasing.

### SUMMARY

Various embodiments of the present disclosure are directed to providing a memory device capable of process simplification and cost reduction, and a method for manufacturing the same.

In an embodiment of the present disclosure, a memory device may include a substrate including a cell area where memory cells are disposed and an extended area outside the cell area; a first gate electrode layer buried in the substrate and extending from the cell area to the extended area in a set direction, an upper surface of the first gate electrode layer in the cell area being located at the same level as the upper surface of the first gate electrode layer in the extended area; a second gate electrode layer disposed on the first gate electrode layer, and extending from the cell area to the extended area in the set direction; and a word line contact located in the extended area, and extending into the second gate electrode layer in a vertical direction, vertical to in the set direction.

In an embodiment of the present disclosure, a memory device may include a substrate including a cell area where memory cells are disposed and an extended area outside the cell area; a first gate electrode layer buried in the substrate, and extending from the cell area to the extended area in a set direction; a second gate electrode layer disposed on the first gate electrode layer and extending from the cell area to the extended area in the set direction, a thickness of the second gate electrode layer in the extended area being substantially the same as the thickness of the second gate electrode layer in the cell area; and a word line contact located in the extended area, and extending into the second gate electrode layer in a vertical direction, vertical to in the set direction.

In an embodiment of the present disclosure, a method for manufacturing a memory device may include forming a first gate electrode layer in a substrate including a cell area where memory cells are disposed and an extended area outside the cell area; forming a second gate electrode layer on the first gate electrode layer; forming, in the extended area, a through hole that penetrates the second gate electrode layer in a vertical direction; and forming a word line contact to fill the through hole.

According to the embodiments of the present disclosure, the manufacturing process of a memory device may be simplified, and the manufacturing cost may be reduced.

### BRIEF DESCRIPTION OF THE DRAWINGS

FIG. 1 is a view illustrating a planar structure of a memory device according to embodiments of the present disclosure.

FIG. 2 is a view illustrating a cross-sectional structure of the memory device according to the embodiments of the present disclosure.

FIG. 3 is an enlarged view of parts 10 and 11 of FIG. 2.

FIG. 4 is a view illustrating an alternative embodiment different from FIG. 3.

FIG. 5 to FIG. 10 are views illustrating a method for manufacturing a memory device according to embodiments of the present disclosure.

FIG. 11 and FIG. 12 are views illustrating across-sectional structure of a memory device different from the memory device according to the embodiments of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present specification. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

In the accompanying drawings, three directions that are parallel to the upper surface of a substrate are defined as a first direction FD, a second direction SD and a third direction TD, respectively, and a direction that vertically protrudes from the upper surface of the substrate is defined as a fourth direction VD. The first direction FD and the second direction SD may be substantially perpendicular to each other. The fourth direction VD is perpendicular to the first direction FD, the second direction SD and the third direction TD. In the following description, the term ‘vertical’ or ‘vertical direction’ will be used as having substantially the same meaning as the fourth direction VD. In the drawings, a direction indicated by an arrow and a direction opposite thereto represent the same direction.

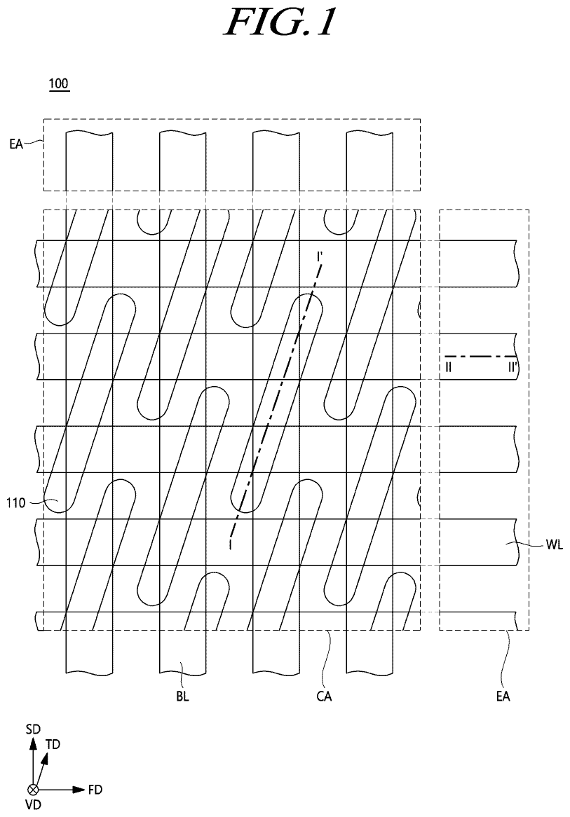

FIG. 1 is a view illustrating a planar structure of a memory device 100 according to embodiments of the present disclosure.

Referring to FIG. 1, the memory device 100 includes a cell area CA and an extended area EA. The cell area CA is an area where memory cells are disposed. In the cell area CA, the memory device 100 includes active areas 110, bit lines BL and word lines WL. The word lines WL cross the active areas 110. The word lines WL extend in the first direction FD. The word lines WL are disposed parallel to each other in the second direction SD. In an embodiment, two corresponding word lines WL may cross each active area 110.

The bit lines BL cross the active areas 110. The bit lines BL extend in the second direction SD. The bit lines BL are disposed parallel to each other in the first direction FD. The bit lines BL cross the word lines WL. The bit lines BL may be orthogonal to the word lines WL. In an embodiment, a corresponding bit line BL may cross at least one active area 110.

The extended area EA is disposed outside the cell area CA in the first direction FD. The extended area EA may be an area where a contact for connecting each of the memory cells in the cell area CA to a peripheral circuit is disposed. The memory device 100 may further include, outside the extended area EA, a peripheral area where peripheral circuits are disposed. The memory cells in the cell area CA and the peripheral circuits in the peripheral area may be connected to each other through contacts disposed in the extended area EA. For example, a contact disposed in the extended area EA may contact a word line WL in the extended area EA. The contact may be connected to a sub word line driver that is located in the peripheral area. That is, the word line WL may be connected to the sub word line driver through the contact.

The extended area EA is disposed outside the cell area CA in the second direction SD. The memory cells in the cell area CA and peripheral circuits in the peripheral area may be connected to each other through contacts in the extended area EA located outside the cell area CA in the second direction SD. For example, a contact disposed in the extended area EA may contact a bit line BL in the extended area EA. The contact may be connected to a sense amplifier that is located in the peripheral area. That is, the bit line BL may be connected to the sense amplifier through the contact.

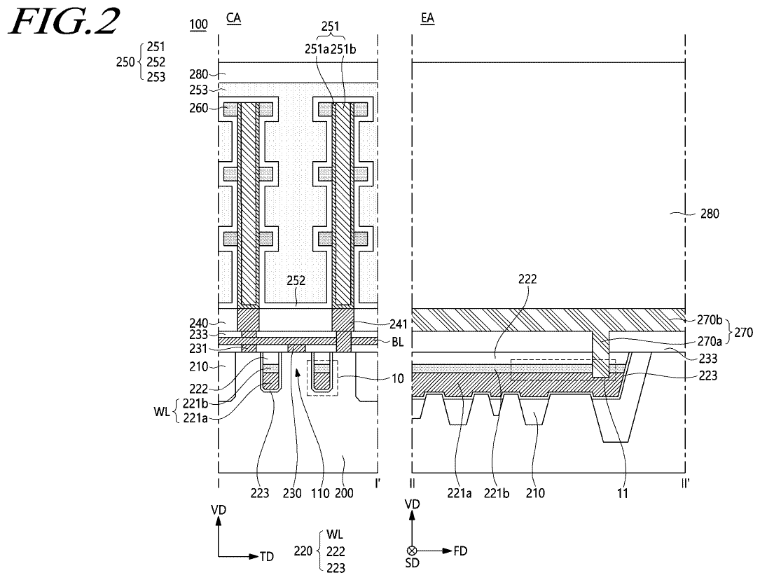

FIG. 2 is a view illustrating a cross-sectional structure of the memory device according to the embodiments of the present disclosure. In FIG. 2, a left side illustrates a cross-sectional view of the memory device 100 taken line I-I′ in FIG. 1, and a right side illustrates a cross-sectional view of the memory device 100 taken lines II-II′ in FIG. 1.

Referring to FIG. 2, the memory device 100 includes a substrate 200, an isolation layer 210, a gate structure 220, a bit line contact 230, a bit line BL, an isolation insulating layer 233, a contact plug 231, a first insulating layer 240, a landing pad 241, a support layer 260, a capacitor 250, a word line contact 270, and a second insulating layer 280.

The substrate 200 may include a semiconductor substrate such as a silicon wafer or a silicon-on-insulator (SOI) wafer. The substrate 200 may include a III-V group semiconductor substrate, for example, a compound semiconductor substrate such as GaAs. The substrate 200 may include monocrystalline silicon, polysilicon, amorphous silicon, monocrystalline silicon germanium, polycrystalline silicon germanium, carbon-doped silicon or a combination thereof.

The substrate 200 includes at least one isolation layer 210. The isolation layer 210 may be formed using a trench isolation technology such as shallow trench isolation (STI). The isolation layer 210 may include silicon oxide, silicon nitride, silicon oxynitride, low-k dielectric, high-k dielectric or a combination thereof.

In the cell area CA, the gate structure 220 may be buried in the active area 110 of the substrate 200. The gate structure 220 includes a word line WL, a gate capping layer 222 and a gate insulating layer 223. The upper surface of the word line WL is located at a level lower than the upper surface of the isolation layer 210. The word line WL may be a buried gate or a buried word line. The word line WL may include a first gate electrode layer 221a and a second gate electrode layer 221b. The second gate electrode layer 221b is disposed on the first gate electrode layer 221a. The gate capping layer 222 is disposed on the second gate electrode layer 221b of the word line WL. The gate insulating layer 223 surrounds the side surfaces of the word line WL and the gate capping layer 222.

Each of the first gate electrode layer 221a and the second gate electrode layer 221b may include a conductive material such as metal, metal oxide, metal nitride, metal silicide, polysilicon, conductive carbon or a combination thereof. The gate capping layer 222 may include silicon oxide, silicon nitride, silicon oxynitride, low-k dielectric, high-k dielectric or a combination thereof. The gate insulating layer 223 may include silicon oxide, silicon nitride, silicon oxynitride, high-k dielectric or a combination thereof.

In the cell area CA, the bit line contact 230, the contact plug 231 and the isolation insulating layer 233 are disposed on the active area 110 of the substrate 200.

The bit line BL is disposed on the bit line contact 230. The bit line BL may be arranged in a direction perpendicular to the word line WL. The bit line BL might not contact the contact plug 231. For example, at least one insulating layer or spacer may be additionally disposed between the bit line BL and the contact plug 231.

The contact plug 231 overlaps the active area 110 of the substrate 200 in the vertical direction VD. The lower surface of the contact plug 231 contacts the active area 110. The upper surface of the contact plug 231 contacts the landing pad 241.

In the cell area CA, the first insulating layer 240 and the landing pad 241 are disposed on the isolation insulating layer 233 and the contact plug 231. The landing pad 241 overlaps the contact plug 231 in the vertical direction VD.

Each of the bit line contact 230, the bit line BL, the contact plug 231 and the landing pad 241 may include a conductive material such as metal, metal oxide, metal nitride, metal silicide, polysilicon, conductive carbon or a combination thereof. Each of the isolation insulating layer 233 and the first insulating layer 240 may include silicon oxide, silicon nitride, silicon oxynitride, low-k dielectric, high-k dielectric or a combination thereof.

In the cell area CA, the capacitor 250 is disposed on the first insulating layer 240 and the landing pad 241. The capacitor 250 includes a lower electrode 251, a dielectric layer 252 and an upper electrode 253.

The lower electrode 251 may correspond one-to-one to the landing pad 241. The lower electrode 251 overlaps the landing pad 241 in the vertical direction VD. The lower electrode 251 may include a first lower electrode 251a and a second lower electrode 251b. The lowermost surface of the first lower electrode 251a contacts the upper surface of the landing pad 241. The second lower electrode 251b contacts the first lower electrode 251a. The second lower electrode 251b fills the space formed between the inner side surfaces of one first lower electrode 251a. In an embodiment, as the second lower electrode 251b fills the space formed between the inner side surfaces of one first lower electrode 251a, it is possible to prevent the leaning of the first lower electrode 251a. In FIG. 2, the lower electrode 251 is illustrated in a pillar shape, but is not limited thereto. The lower electrode 251 may also have a cylinder shape.

The support layer 260 is disposed on the side surface of the lower electrode 251. Each support layer 260 may contact a partial area of the side surface of the lower electrode 251. In an embodiment, the support layer 260 may prevent the leaning of the lower electrode 251. Support layers 260 may be disposed to be spaced apart from each other in the vertical direction VD.

The dielectric layer 252 is disposed along the profile of the surfaces of the lower electrode 251 and the support layer 260. The dielectric layer 252 may be disposed to cover the surface of the lower electrode 251, the surface of the support layer 260 and the upper surface of the first insulating layer 240. In an embodiment, the lowermost surface of the dielectric layer 252 may form substantially the same plane as the lowermost surface of the lower electrode 251. Alternatively, an etch stop layer may be additionally disposed between the dielectric layer 252 and the first insulating layer 240. In this case, the lowermost surface of the dielectric layer 252 may be located at a level higher than the lowermost surface of the lower electrode 251.

The upper electrode 253 is disposed on the surface of the dielectric layer 252. The upper electrode 253 is disposed to fill the space formed between the outer side surfaces of the dielectric layer 252. The upper surface of the upper electrode 253 may be located at a level higher than the upper surface of the lower electrode 251 in the vertical direction VD. The second insulating layer 280 is disposed on the upper electrode 253.

Each of the first lower electrode 251a, the second lower electrode 251b and the upper electrode 253 may include a conductive material such as metal, metal oxide, metal nitride, metal silicide, polysilicon, conductive carbon or a combination thereof. In an embodiment, the first lower electrode 251a may be metal nitride, and the second lower electrode 251b may be polysilicon. The support layer 260 may include nitride such as silicon nitride or silicon carbon nitride. The dielectric layer 252 may include high-k dielectric, silicon oxide, silicon nitride or a combination thereof.

In the extended area EA, at least one isolation layer 210 is buried in the substrate 200. The gate insulating layer 223 is disposed on the isolation layer 210. The first gate electrode layer 221a, the second gate electrode layer 221b, the gate capping layer 222 and the isolation insulating layer 233 are sequentially disposed on the gate insulating layer 223.

The gate insulating layer 223, the first gate electrode layer 221a, the second gate electrode layer 221b, the gate capping layer 222 and the isolation insulating layer 233 may extend from the cell area CA to the extended area EA in the first direction FD. In an embodiment, in the extended area EA, each of the first gate electrode layer 221a and the second gate electrode layer 221b may have a flat upper surface.

In the extended area EA, the word line contact 270 is disposed on the isolation insulating layer 233. The word line contact 270 includes a contact section 270a and an extended section 270b. The contact section 270a protrudes toward the substrate 200 in the vertical direction VD. The extended section 270b is continuous with the contact section 270a and extends in the first direction FD on the isolation insulating layer 233. The contact section 270a extends into the first gate electrode layer 221a by penetrating the isolation insulating layer 233, the gate capping layer 222 and the second gate electrode layer 221b in the vertical direction VD. In some embodiments, the extended section 270b may extend further to the outside of the extended area EA in the first direction FD. In an embodiment, the extended section 270b may be connected to a sub word line driver outside the extended area EA. The word line contact 270 may include a conductive material such as metal, metal oxide, metal nitride, metal silicide, polysilicon, conductive carbon or a combination thereof. The second insulating layer 280 is disposed on the word line contact 270.

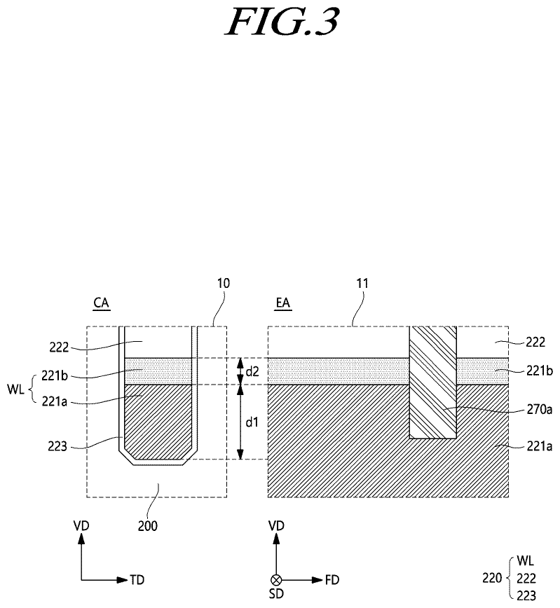

FIG. 3 is an enlarged view of parts 10 and 11 of FIG. 2.

Referring to FIG. 3, the first gate electrode layer 221a and the second gate electrode layer 221b are buried in the substrate 200. The first gate electrode layer 221a and the second gate electrode layer 221b extend from the cell area CA to the extended area EA in the first direction FD.

In an embodiment, the first gate electrode layer 221a may include titanium nitride, tungsten, titanium, tantalum, aluminum, molybdenum, silicon, silicon germanium, polysilicon or a combination thereof.

In an embodiment, the upper surface of the first gate electrode layer 221a in the cell area CA may be located at substantially the same level as the upper surface of the first gate electrode layer 221a in the extended area EA. In the present specification, being substantially the same means including a difference due to a process error.

A thickness d2 of the second gate electrode layer 221b in the cell area CA may be substantially the same as the thickness of the second gate electrode layer 221b in the extended area EA. In an embodiment, the thickness d2 of the second gate electrode layer 221b may be greater than or equal to 10 angstroms and less than or equal to 250 angstroms.

The second gate electrode layer 221b may include a material different from a material that forms the first gate electrode layer 221a. In an embodiment, the second gate electrode layer 221b may include titanium nitride, tungsten, titanium, tantalum, aluminum, molybdenum, silicon, silicon germanium, polysilicon or a combination thereof. In an embodiment, the second gate electrode layer 221b may include a material with a lower work function than the material that forms the first gate electrode layer 221a. When the second gate electrode layer 221b includes a material with a lower work function than the material that forms the first gate electrode layer 221a, a gate-induced drain leakage (GIDL) phenomenon may be prevented.

In an embodiment, the upper surface of the second gate electrode layer 221b in the cell area CA may be located at substantially the same level as the upper surface of the second gate electrode layer 221b in the extended area EA. In an embodiment, the thickness d2 of the second gate electrode layer 221b may be constant in the cell area CA and the extended area EA.

In the cell area CA, a maximum thickness d1 of the first gate electrode layer 221a may be greater than the thickness d2 of the second gate electrode layer 221b.

In the cell area CA, the gate insulating layer 223 surrounds the side surface and the lower surface of the first gate electrode layer 221a and the side surface of the second gate electrode layer 221b. In an embodiment, the thickness of the gate insulating layer 223 may be greater than or equal to 20 angstroms and less than or equal to 45 angstroms.

In general, the amount of gate-induced drain leakage current may change depending on the thickness of the second gate electrode layer 221b. For example, when the thickness of the second gate electrode layer 221b is great, the amount of gate-induced drain leakage current may be lesser. When the thickness of the gate insulating layer 223 is less than or equal to 45 angstroms, the influence of the thickness of the second gate electrode layer 221b on the amount of gate-induced drain leakage current may decrease.

The lower surface of the contact section 270a of the word line contact 270 in the extended area EA contacts the first gate electrode layer 221a. The side surface of the contact section 270a of the word line contact 270 contacts the first gate electrode layer 221a and the second gate electrode layer 221b. In an embodiment, the word line contact 270 may transmit a voltage for turning on a transistor included in a memory cell from a sub word line driver to the word line WL.

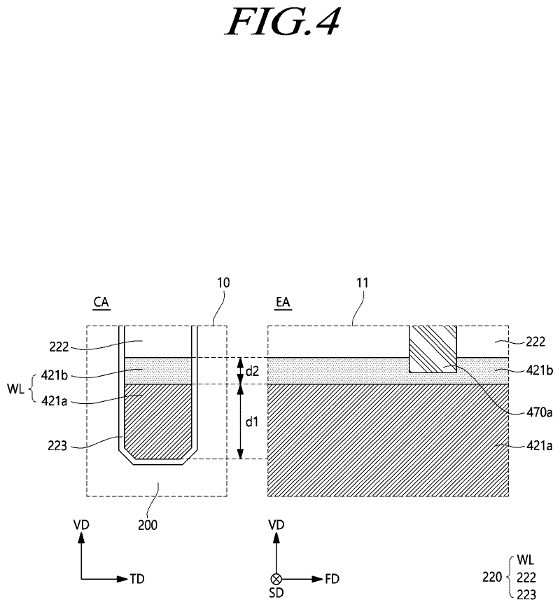

FIG. 4 is a view illustrating an alternative embodiment different from FIG. 3.

In the following embodiment, descriptions of components that are substantially the same as or similar to those in the previous embodiment of FIG. 3 will be omitted.

Referring to FIG. 4, the gate structure 220 includes the word line WL, the gate capping layer 222 and the gate insulating layer 223. The word line WL includes a first gate electrode layer 421a and a second gate electrode layer 421b that is disposed on the first gate electrode layer 421a.

In the extended area EA, a contact section 470a of the word line contact 270 extends through the gate capping layer 222 into the second gate electrode layer 421b in the vertical direction VD. The side surface and the lower surface of the contact section 470a contacts the second gate electrode layer 421b. The lower surface of the contact section 470a is located at a level higher than the upper surface of the first gate electrode layer 421a.

In an embodiment, the second gate electrode layer 421b may include a material with a lower work function than a material that forms the first gate electrode layer 421a. In an embodiment, the second gate electrode layer 421b may include a material with a lower resistance than the material that forms the first gate electrode layer 421a. When the second gate electrode layer 421b includes a material with a lower resistance than the first gate electrode layer 421a, the contact section 470a of the word line contact 270 may transmit a voltage for turning on a transistor included in a memory cell to the word line WL through the second gate electrode layer 421b.

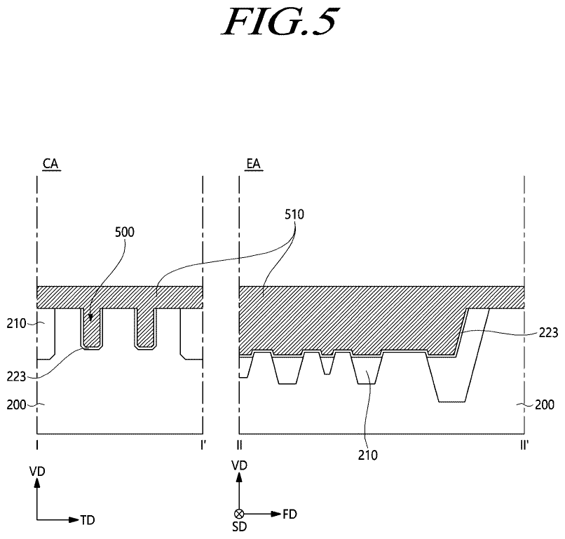

FIG. 5 to FIG. 10 are views illustrating a method for manufacturing a memory device according to embodiments of the present disclosure.

Referring to FIG. 5, an isolation layer 210 that delimits an active area is formed in a substrate 200 in a cell area CA. A gate trench 500 which crosses the active area in the first direction FD is formed in the substrate 200. In an extended area EA, a portion of the upper area of the substrate 200 may be removed so that the upper surface of the substrate 200 is recessed downward in the vertical direction VD. The isolation layer 210 is formed to fill the recessed space of the substrate 200. The recessed space of the substrate 200 and the isolation layer 210 that fills the recessed space may be formed in various sizes.

A gate insulating layer 223 is formed on the side surface and the lower surface of the gate trench 500 of the cell area CA and on the substrate 200 and the isolation layer 210 of the extended area EA. The gate insulating layer 223 is formed along the steps of underlying layers. In an embodiment, the gate insulating layer 223 may conformally cover the side surface and the lower surface of the gate trench 500 of the cell area CA, the upper surface and portions of the side surface of the substrate 200 in the extended area EA, and the upper surface of the isolation layer 210. In an embodiment, the thickness of the gate insulating layer 223 may be greater than or equal to 20 angstroms and less than or equal to 45 angstroms. In the cell area CA, the gate insulating layer 223 that is formed in an area other than an area where the gate trench 500 is disposed may be removed.

In the cell area CA and the extended area EA, a gate electrode material 510 is formed on the gate insulating layer 223 and the substrate 200. In an embodiment, the gate electrode material 510 may be formed to a level higher than the upper surface of the substrate 200. The gate electrode material 510 may include the same material as the first gate electrode layer 221a described above with reference to FIG. 2 to FIG. 4. The gate electrode material 510 may include titanium nitride, tungsten, titanium, tantalum, aluminum, molybdenum, silicon, silicon germanium, polysilicon or a combination thereof.

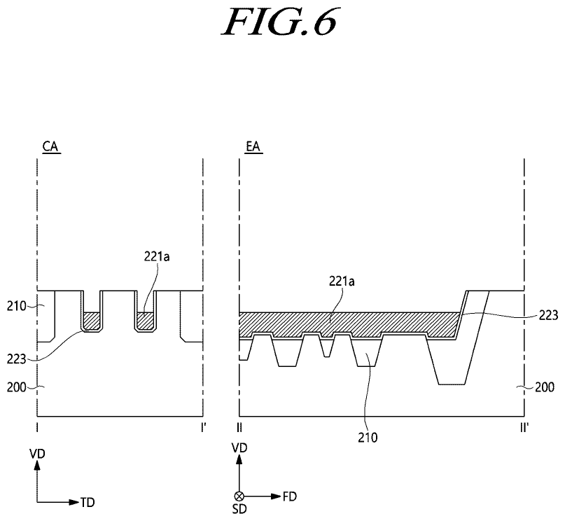

Referring to FIG. 6, by removing portions of the gate electrode material 510 in the cell area CA and the extended area EA, a first gate electrode layer 221a is formed. A process of forming the first gate electrode layer 221a may include an etch-back process. The upper surface of the first gate electrode layer 221a in the cell area CA may form substantially the same plane as the upper surface of the first gate electrode layer 221a in the extended area EA.

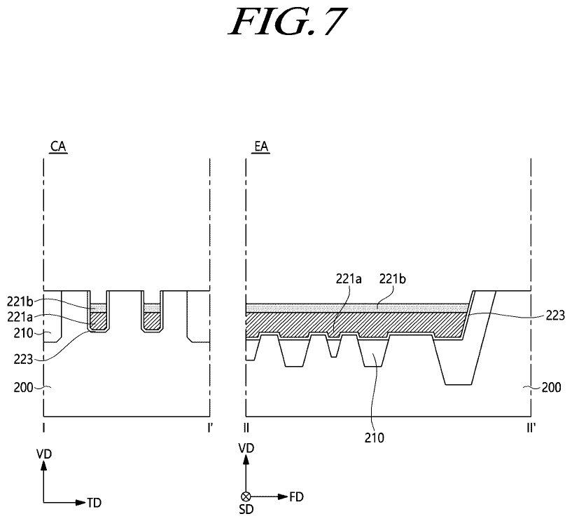

Referring to FIG. 7, in the cell area CA and the extended area EA, a second gate electrode layer 221b is formed on the first gate electrode layer 221a. A process of forming the second gate electrode layer 221b may include an etch-back process. The upper surface of the second gate electrode layer 221b in the cell area CA may form substantially the same plane as the upper surface of the second gate electrode layer 221b in the extended area EA. In an embodiment, the thickness of the second gate electrode layer 221b in the cell area CA may be substantially the same as the thickness of the second gate electrode layer 221b in the extended area EA. In an embodiment, the thickness of the second gate electrode layer 221b may be greater than or equal to 10 angstroms and less than or equal to 250 angstroms.

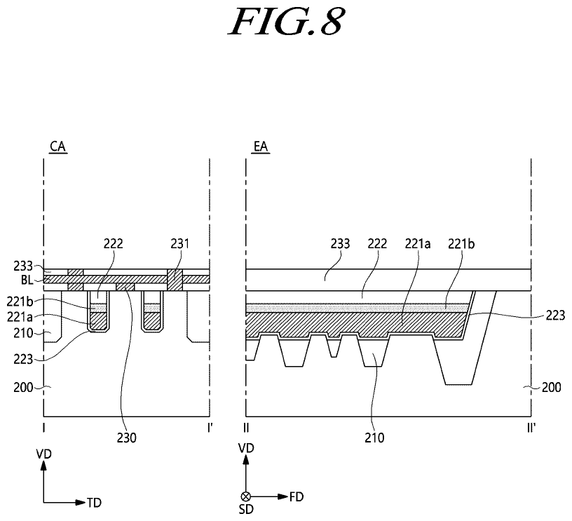

Referring to FIG. 8, in the cell area CA and the extended area EA, a gate capping layer 222 is formed on the second gate electrode layer 221b. In the cell area CA, a bit line contact 230, a bit line BL, a contact plug 231 and an isolation insulating layer 233 are formed on the gate capping layer 222. The contact plug 231 may be formed to penetrate the isolation insulating layer 233 and contact the active area of the substrate 200 after the isolation insulating layer 233 is formed. In the extended area EA, the isolation insulating layer 233 is formed on the gate capping layer 222. In an embodiment, the upper surface of the isolation insulating layer 233 in the cell area CA may form substantially the same plane as the upper surface of the isolation insulating layer 233 in the extended area EA.

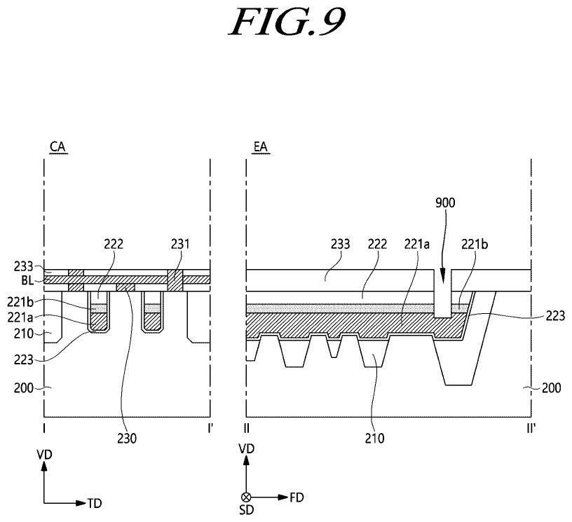

Referring to FIG. 9, in the extended area EA, a through hole 900 is formed to extend into the first gate electrode layer 221a through the isolation insulating layer 233, the gate capping layer 222 and the second gate electrode layer 221b in the vertical direction VD.

The lower surface of the through hole 900 contacts the first gate electrode layer 221a. The lower surface of the through hole 900 is located at a level lower than the upper surface of the first gate electrode layer 221a. The side surface of the through hole 900 contacts the first gate electrode layer 221a and the second gate electrode layer 221b.

A process of forming the through hole 900 may include an etching process. In an embodiment, the etching process may include a directional etching process. In an embodiment, portions of the isolation insulating layer 233, the gate capping layer 222 and the second gate electrode layer 221b may be removed through the directional etching process.

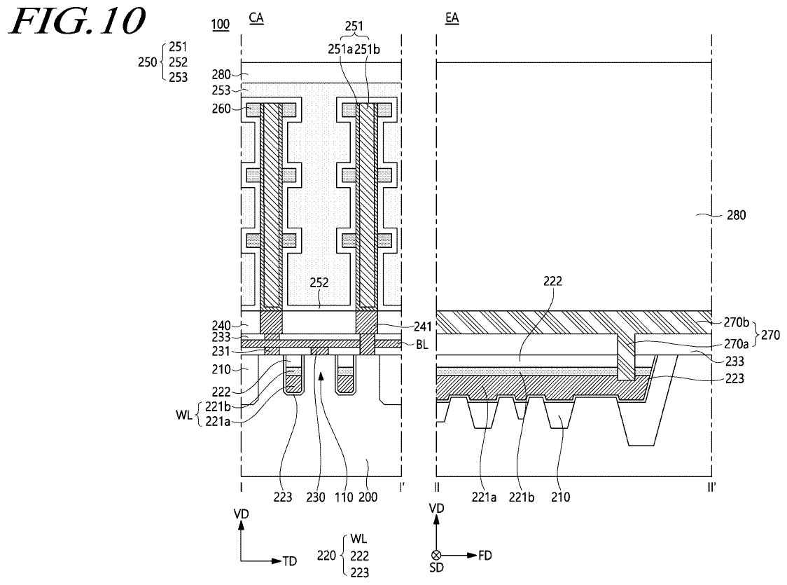

Referring to FIG. 10, in the cell area CA, a first insulating layer 240 is formed on the isolation insulating layer 233 and the contact plug 231. After the first insulating layer 240 is formed, a landing pad 241 that penetrates the first insulating layer 240 in the vertical direction VD is formed.

A lower electrode 251 and a support layer 260 are formed on the landing pad 241. The lower electrode 251 is formed to overlap the landing pad 241 in the vertical direction VD. The lower surface of the lower electrode 251 is formed to contact the upper surface of the landing pad 241. A process of forming the lower electrode 251 may include processes of forming a plurality of insulating layers on the first insulating layer 240 and the landing pad 241, forming a hole penetrating the plurality of insulating layers and then depositing an electrode material filling the hole. In an embodiment, a process of forming the support layer 260 may include a process of, after depositing the electrode material, etching portions of the plurality of insulating layers through a dip-out process.

A dielectric layer 252 is formed along the profile of the surfaces of the first insulating layer 240, the lower electrode 251 and the support layer 260. An upper electrode 253 is formed on the dielectric layer 252. A second insulating layer 280 is formed on the upper electrode 253.

In the extended area EA, a word line contact 270 is formed in the through hole 900 and on the isolation insulating layer 233. In an embodiment, the word line contact 270 may be formed in the same process as a process of forming the landing pad 241. A contact section 270a of the word line contact 270 is formed to fill the inside of the through hole 900. The second insulating layer 280 is formed on the word line contact 270.

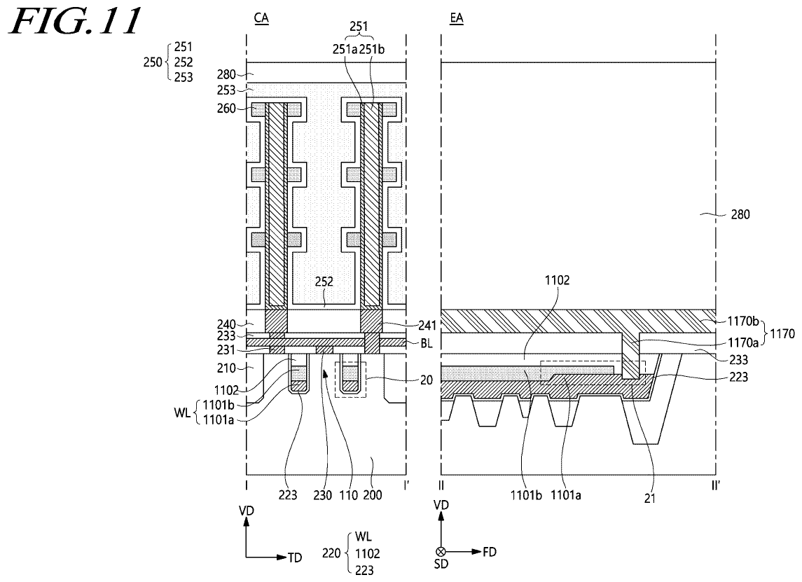

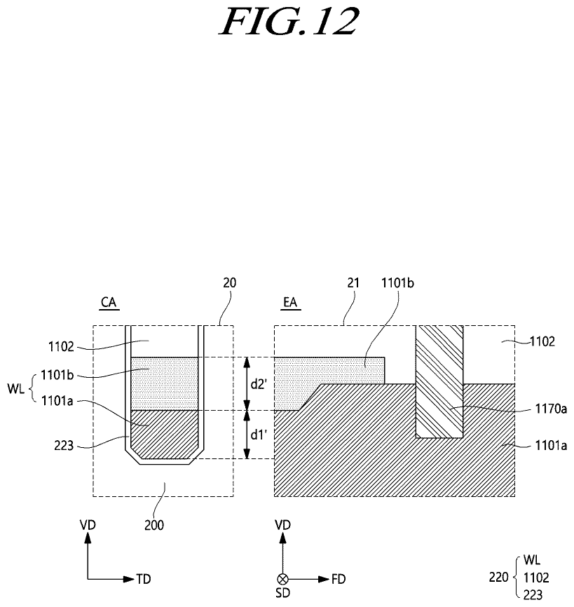

FIG. 11 and FIG. 12 are views illustrating across-sectional structure of a memory device different from the memory device according to the embodiments of the present disclosure.

Referring to FIG. 11 and FIG. 12, in a partial area of an extended area EA, a first gate electrode layer 1101a may be deposited more than that of the other area in the extended area EA. For example, in the extended area EA, the upper surface of the first gate electrode layer 1101a may include a step. A portion of the upper surface of the first gate electrode layer 1101a in the extended area EA may be located at a level higher than the upper surface of the first gate electrode layer 1101a in a cell area CA. A maximum thickness d1′ of the first gate electrode layer 1101a in the cell area CA may be less than the maximum thickness d1 of the first gate electrode layer 221a in the cell area CA described above with reference to FIG. 3.

In the extended area EA, a portion of a second gate electrode layer 1101b located on the raised upper surface of the first gate electrode layer 1101a may be removed. As the portion of the second gate electrode layer 1101b is removed, the upper surface of the first gate electrode layer 1101a may be exposed. The upper surface of the second gate electrode layer 1101b in the cell area CA may form substantially the same plane as the upper surface of the second gate electrode layer 1101b in the extended area EA. A thickness d2′ of the second gate electrode layer 1101b in the cell area CA may be greater than the thickness of the portion of the second gate electrode layer 1101b in the extended area EA. The thickness d2′ of the second gate electrode layer 1101b in the cell area CA may be greater than the thickness d2 of the second gate electrode layer 221b described above with reference to FIG. 3.

A portion of the second gate electrode layer 1101b located on the raised upper surface of the first gate electrode layer 1101a might not be removed. Alternatively, the upper surface of the first gate electrode layer 1101a in an area where the portion of the second gate electrode layer 1101b is removed may be located at the same level as the upper surface of the first gate electrode layer 1101a in the cell area CA.

The sum of the maximum thickness d1′ of the first gate electrode layer 1101a in the cell area CA and the thickness d2′ of the second gate electrode layer 1101b in the cell area CA may be the same as the sum of the maximum thickness d1 of the first gate electrode layer 221a and the thickness d2 of the second gate electrode layer 221b in the cell area CA described above with reference to FIG. 3.

A contact section 1170a of a word line contact 1170 extends through the gate capping layer 1102 into the first gate electrode layer 1101a in the vertical direction VD. The word line contact 1170 extends into the first gate electrode layer 1101a in an area where the upper surface of the first gate electrode layer 1101a is exposed.

As described above, the greater the thickness of the second gate electrode layer 1101b is, the more the amount of gate-induced drain leakage current may decrease. Therefore, when forming a memory cell, as illustrated in FIG. 11 and FIG. 12, in a state in which the thickness of a word line WL in the cell area CA is kept constant, the thickness of the first gate electrode layer 1101a may be reduced and the thickness of the second gate electrode layer 1101b may be increased.

However, when the thickness of the second gate electrode layer 1101b increases, it is difficult to form a word line contact through the second gate electrode layer 1101b. Therefore, a process of locally opening the second gate electrode layer 1101b in the extended area EA is additionally required.

In addition, when the thickness of the first gate electrode layer 1101a decreases, there is a risk for the first gate electrode layer 1101a to be cut in the extended area EA. Therefore, a process of locally increasing the thickness of the first gate electrode layer 1101a in the extended area EA is additionally required. Referring again to FIG. 2, the upper surface of the first gate electrode layer 221a in the cell area CA may be located at substantially the same level as the upper surface of the first gate electrode layer 221a in the extended area EA. In an embodiment, the thickness d2 of the second gate electrode layer 221b may be greater than or equal to 10 angstroms and less than or equal to 250 angstroms. In the cell area CA, the maximum thickness d1 of the first gate electrode layer 221a may be greater than the thickness d2 of the second gate electrode layer 221b. In an embodiment, the thickness of the gate insulating layer 223 may be greater than or equal to 20 angstroms and less than or equal to 45 angstroms. The contact section 270a of the word line contact 270 extends into the first gate electrode layer 221a by penetrating the isolation insulating layer 233, the gate capping layer 222 and the second gate electrode layer 221b in the vertical direction VD.

According to the embodiments of the present disclosure, when the thickness of the gate insulating layer 223 is formed to be thin, the influence of the thickness of the second gate electrode layer 221b on the amount of gate-induced drain leakage current may decrease. That is, the thickness of the second gate electrode layer 221b does not need to be significantly increased to prevent a gate-induced drain leakage phenomenon. Because the thickness of the second gate electrode layer 221b does not need to be increased, a process of locally opening the second gate electrode layer 221b when forming the word line contact 270 may be omitted. When the thickness of the second gate electrode layer 221b is thin, it is easy to penetrate the second gate electrode layer 221b, and thus, a separate process for opening the second gate electrode layer 221b is not required when forming the word line contact 270. Therefore, the process may be simplified.

In addition, because there is no need to increase the thickness of the second gate electrode layer 221b, there is no need to reduce the thickness of the first gate electrode layer 221a. Because the thickness of the first gate electrode layer 221a does not need to be reduced, a defect due to the cut of the first gate electrode layer 221a in the extended area EA may be prevented. Moreover, because the volume of the first gate electrode layer 221a disposed in the cell area CA and the extended area EA does not need to be reduced, power loss due to the resistance of the word line WL itself when a voltage is supplied to a memory cell through the word line WL may be reduced.

While the detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope. Furthermore, the embodiments may be combined to form additional embodiments.

What is claimed is:

1. A memory device comprising:
a substrate including a cell area where memory cells are disposed and an extended area outside the cell area;
a first gate electrode layer buried in the substrate and extending from the cell area to the extended area in a set direction, an upper surface of the first gate electrode layer in the cell area being located at substantially the same level as the upper surface of the first gate electrode layer in the extended area;
a second gate electrode layer disposed on the first gate electrode layer, and extending from the cell area to the extended area in the set direction; and
a word line contact located in the extended area, and extending into the second gate electrode layer in a vertical direction, vertical to the set direction.

2. The memory device according to claim 1, wherein the thickness of the second gate electrode layer is greater than or equal to 10 angstroms and less than or equal to 250 angstroms.

3. The memory device according to claim 1, wherein a side surface of the word line contact contacts the second gate electrode layer.

4. The memory device according to claim 1, wherein a lower surface of the word line contact is located at a level higher than the upper surface of the first gate electrode layer.

5. The memory device according to claim 1, wherein the word line contact further extends into the first gate electrode layer through the second gate electrode layer in the vertical direction.

6. The memory device according to claim 1, wherein an upper surface of the second gate electrode layer in the cell area is located at substantially the same level as the upper surface of the second gate electrode layer in the extended area.

7. The memory device according to claim 1, wherein the thickness of the second gate electrode layer in the extended area is substantially the same as the thickness of the second gate electrode layer in the cell area.

8. The memory device according to claim 1, further comprising:
a gate insulating layer surrounding a lower surface and a side surface of the first gate electrode layer and a side surface of the second gate electrode layer,
wherein the thickness of the gate insulating layer is greater than equal to 20 angstroms and less than or equal to 45 angstroms.

9. The memory device according to claim 1, wherein the second gate electrode layer includes a material with a lower work function than a material of the first gate electrode layer.

10. The memory device according to claim 1, wherein the second gate electrode layer includes titanium nitride, tungsten, titanium, tantalum, aluminum, molybdenum, silicon, silicon germanium, polysilicon or a combination thereof.

11. The memory device according to claim 1, wherein the first gate electrode layer and the second gate electrode layer configure a word line.

12. A memory device comprising:
a substrate including a cell area where memory cells are disposed and an extended area outside the cell area;
a first gate electrode layer buried in the substrate, and extending from the cell area to the extended area in a set direction;
a second gate electrode layer disposed on the first gate electrode layer and extending from the cell area to the extended area in the set direction, a thickness of the second gate electrode layer in the extended area being substantially the same as the thickness of the second gate electrode layer in the cell area; and
a word line contact located in the extended area, and extending into the second gate electrode layer in a vertical direction, vertical to the set direction.

13. The memory device according to claim 12, wherein the thickness of the second gate electrode layer is greater than or equal to 10 angstroms and less than or equal to 250 angstroms.

14. The memory device according to claim 12, wherein a lower surface of the word line contact is located at a level higher than an upper surface of the first gate electrode layer.

15. The memory device according to claim 12, wherein the word line contact further extends into the first gate electrode layer through the second gate electrode layer in the vertical direction.

16. The memory device according to claim 12, further comprising:
a gate insulating layer surrounding a lower surface and a side surface of the first gate electrode layer and a side surface of the second gate electrode layer,
wherein the thickness of the gate insulating layer is greater than or equal to 20 angstroms and less than or equal to 45 angstroms.

17. The memory device according to claim 12, wherein an upper surface of the second gate electrode layer in the cell area is located at substantially the same level as the upper surface of the second gate electrode layer in the extended area.

18. The memory device according to claim 12, wherein a thickness of the first gate electrode layer in the extended area is greater than the thickness of the first gate electrode layer in the cell area.

19. A method for manufacturing a memory device, the method comprising:
forming a first gate electrode layer in a substrate including a cell area where memory cells are disposed and an extended area outside the cell area;
forming a second gate electrode layer on the first gate electrode layer;
forming, in the extended area, a through hole that penetrates the second gate electrode layer in a vertical direction; and
forming a word line contact to fill the through hole.

20. The method according to claim 19, wherein a thickness of the second gate electrode layer is greater than or equal to 10 angstroms and less than or equal to 250 angstroms.
